(19) United States
(12) Patent Application Publication
(10) Pub. No.: US 2016/0099139 A1
(43) Pub. Date: Apr. 7, 2016

(54) MASS MICROSCOPE APPARATUS

(71) Applicant: CANON KABUSHIKI KAISHA, Tokyo (JP)

(72) Inventor: Masafumi Kyogaku, Yokohama-shi (JP)

(21) Appl. No.: 14/874,106

(22) Filed: Oct. 2, 2015

(30) Foreign Application Priority Data
Oct. 6, 2014 (JP) 2014-206015

(51) Int. Cl. H01J 49/40; H01J 37/26; H01J 49/06; H01J 49/10; H01J 37/20

(52) U.S. Cl. CPC H01J 49/40; H01J 49/10; H01J 37/20; H01J 49/06; H01J 37/261; H01J 2237/2602; H01J 2237/202

(57) ABSTRACT

A mass microscope apparatus includes: a measuring unit including an ionization unit configured to ionize a sample present in an observation region, and a mass spectrometry unit configured to perform mass spectrometry of ions generated by the ionization unit; an object moving device configured to relatively move the observation region as to the sample; and a switching unit configured to switch measurement conditions of the measuring unit depending on whether the mass microscope apparatus is operating in a moving measurement mode where the observation region is moved by the object moving device to sequentially perform measurement by the measuring unit, and a stationary measurement mode where the observation region is stationary and measurement is performed by the measuring unit.

### BACKGROUND OF THE INVENTION

1. Field of the Invention

The present invention relates to a mass microscope apparatus.

2. Description of the Related Art

As of recent, the mass microscope apparatus has been developed. The mass microscope apparatus is capable of visualizing distribution of substances present on the surface of a sample by mass spectrometry. There are expectations for the mass microscope apparatus in applications to comprehensively visualize distribution information of multiple substances making up biological tissue, for example.

Mass spectrometry involves first ionizing substances included in a sample. Mass spectral data is acquired by separating and detecting the generated ions according to mass-to-charge ratio (m/z), thereby acquiring information relating to substances included in the sample. The mass microscope apparatus applying mass spectrometry can acquire substance distribution information by two-dimensionally performing mass spectrometry on the surface of the sample (Japanese Patent Laid-Open No. 2007-157353).

Generally, the observation region of mass microscope apparatuses that can be observed at once is limited to a relatively narrow range (e.g., several hundred μm square or so forth). However, observing biological tissue requires observing a region of a relatively wide area (e.g., several mm square or so forth). In this case, there is the need to sequentially move the observation region to perform observation.

Mass microscope apparatuses need to acquire mass spectral data at a great number of measurement points for a great many types of m/z to acquire a precise spectrum distribution, which takes time for measuring. Moreover, if the number of measurement points and the number of types of m/z to be measured are great, the data size of the acquired mass spectral data becomes massive, and the increase in time for analysis is tremendous. Particularly, the increase in analysis time is pronounced in a case of performing analysis such as multivariate analysis or the like on the acquired mass spectral data.

That is to say, the more precise a mass distribution image acquired for detailed observation is, the longer the amount of time is taken from measurement to display of analysis results. There has been a problem in that, when attempting to acquire and observe images while moving the observation region, quickly viewing analysis results along with moving of the observation region is difficult.

### SUMMARY OF THE INVENTION

A mass microscope apparatus includes a measuring unit including an ionization unit configured to ionize a sample present in an observation region, and a mass spectrometry unit configured to perform mass spectrometry of ions generated by the ionization unit; an object moving device configured to relatively move the observation region as to the sample; and a switching unit configured to switch measurement conditions of the measuring unit depending on whether the mass microscope apparatus is operating in a moving measurement mode where the observation region is moved by the object moving device to sequentially perform measurement by the measuring unit, and a stationary measurement mode where the observation region is stationary and measurement is performed by the measuring unit.

Further features of the present invention will become apparent from the following description of exemplary embodiments with reference to the attached drawings.

### BRIEF DESCRIPTION OF THE DRAWINGS

FIG. 1 is a diagram schematic illustrating the configuration of a mass microscope apparatus according to an embodiment.

FIG. 2 is a diagram schematic illustrating the configuration of the mass microscope apparatus according to an embodiment.

FIGS. 3A and 3B are schematic diagrams illustrating a relationship regarding switching measurement conditions when the observation region is moving and when stationary, in the mass microscope apparatus according to an embodiment.

FIG. 4 is a schematic diagram illustrating a relationship regarding switching measurement conditions (number of measurement points) when the observation region is moving and when stationary, in the mass microscope apparatus according to a first embodiment.

FIG. 5A is a schematic diagram illustrating a relationship regarding switching measurement conditions (number of m/z) when the observation region is moving, in the mass microscope apparatus according to a second embodiment.

FIG. 5B is a diagram illustrating a relationship regarding switching measurement conditions (number of m/z) when the observation region is stationary, in the mass microscope apparatus according to the second embodiment.

FIG. 6A is a schematic diagram illustrating a relationship regarding switching measurement conditions (numerical value range of m/z) when the observation region is moving, in the mass microscope apparatus according to a third embodiment.

FIG. 6B is a diagram illustrating a relationship regarding switching measurement conditions (numerical value range of m/z) when the observation region is stationary, in the mass microscope apparatus according to the third embodiment.

FIG. 7 is a diagram illustrating a relationship regarding switching measurement conditions when the observation region is moving, during preview display, and when stationary, in the mass microscope apparatus according to a fifth embodiment.

### DESCRIPTION OF THE EMBODIMENTS

Several embodiments of a mass microscope apparatus according to the present invention will be described below. It should be understood, though, that the present invention is not restricted to the configurations of these embodiments.

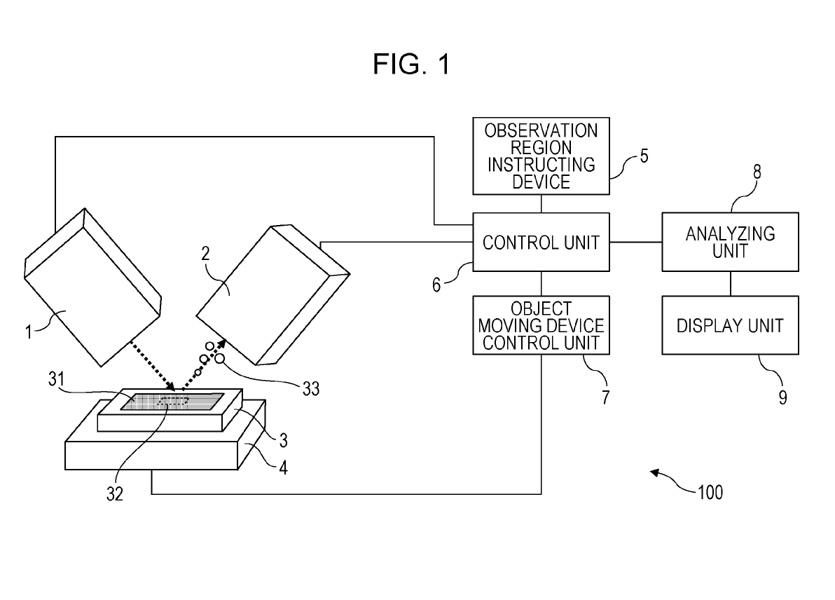

First, a configuration example of a mass microscope apparatus 100 to which an embodiment has been applied (hereinafter, simply “apparatus 100”) will be described with reference to FIG. 1. The apparatus 100 includes an ionization unit 1, a mass spectrometry unit 2, a sample table 3, an object moving device 4, an observation region instructing device 5, a control unit 6, an object moving device control unit 7, an analyzing unit 8, and a display unit 9. The apparatus 100 according to the embodiment can be classified into either a scanning type or a projection type, depending on the method of irradiation of ionization beam.

A scanning type mass microscope apparatus first sections an observation region 32 upon the surface of a sample 31 into multiple fine regions, and performs ionization and mass spectrometry of the constituent of the sample 31 in increments of the fine regions. The fine regions that have been ionized are scanned within the observation region 32, and mass spectrometry is sequentially performed regarding a great number of fine regions (measurement points). Thus, two-dimensional distribution information of mass spectral data within the observation region 32 can be acquired. Note that “mass spectral data” is information acquired as the result of mass spectrometry of ions 33, and is data in which ion detection intensity corresponding to each of multiple mass-to-charge ratios (hereinafter, “m/z”) has been integrated.

A projection type mass microscope apparatus performs batch ionization of the constituent of the sample 31 within a region encompassing at least the observation region 32. Discharged ions 33 are projected onto an ion detector (included in the mass spectrometry unit 2) with positional information maintained. A projection type mass microscope apparatus can markedly reduce time required for measurement, since two-dimensional distribution information of mass spectral data of the constituent within the observation region 32 can be acquired at one time.

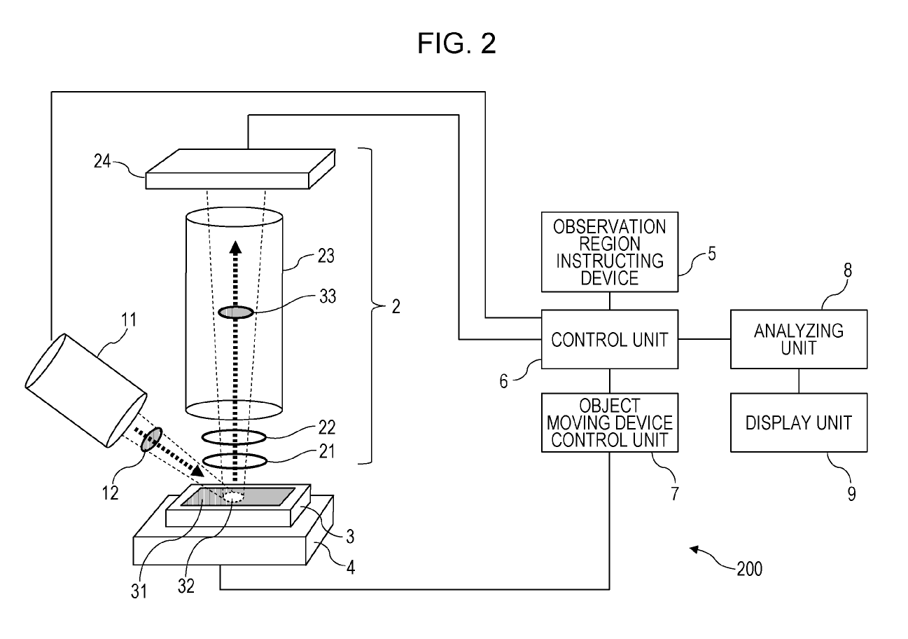

FIG. 2 illustrates a projection type mass microscope apparatus 200. While description will be made here regarding a case where the mass spectrometry unit 2 is a time-of-flight (TOF) mass spectrometer, this is not restrictive.

The projection type mass spectrometry unit 2 according to the embodiment is configured including an extraction electrode 21, an ion optical system 22, a flight tube 23, and an ion detector 24. Ions 33 generated at the sample 31 fly through the inside of the flight tube 23 of the mass spectrometry unit 2 while maintaining the positional relationship of generation of the ions 33 at the surface of the sample 31. The ions 33 which have flown through the inside of the flight tube 23 are then projected on the ion detector 24 and detected.

The extraction electrode 21 is disposed facing the sample table 3, with a gap of around 1 mm to 10 mm therebetween. Extraction voltage Vd of 100 V to 10 kV is applied across the electroconductive sample table 3 and the extraction electrode 21, to extract the ions 33 generated at the sample 31. Note that the polarity of the extraction voltage Vd is charged according to the polarity of the detected ions 33. The generated ions 33 are accelerated by the extraction voltage Vd and input to the flight tube 23. The flight speed of the accelerated ions 33 at this time is inversely proportional to the square root of m/z.

The ion optical system 22 is disposed downstream from the extraction electrode 21. The ion optical system 22 according to the embodiment is a projection optical system, and is configured including multiple electrodes. Changing the applied voltage to the multiple electrodes enables the projection magnification to be optionally changed.

The flight tube 23 is a cylinder metal tube. There is no electric field gradient within the flight tube 23. Accordingly, the ions 33 fly through the flight tube 23 at a constant speed. The flight time is proportionate to the square root of m/z, so measuring the flight time enables the m/z of the ions 33 to be analyzed.

The ion detector 24 is a part that detects the ions 33 which have flown through the flight tube 23 and arrived at the ion detector 24. The ion detector 24 outputs the clock time of detection of the detected ions 33, and also outputs the positional information of the detected ions 33 on the ion detector 24. Any configuration may be used for the ion detector 24, as long as a two-dimensional ion detector that can detect the clock time and positional information of detection of ions. In a case where the ion detector 24 is a pixel type detector where detection elements are arrayed in a two-dimensional layout, the density of the detection elements is fixed. Accordingly, spatial resolution can be improved by increasing the projection magnification as to the ion detector 24.

The ion detector 24 may be of a configuration where a signal detector having a function of detecting the arrival time and positions of charged particles is combined with a micro channel plate (MCP). The MCP amplifies electrons generated by the input of ions, and discharges the electrons from a backside. The electrons amplified at the MCP are detected at the signal detector. The signal detector may be a pixel-type semiconductor detector or a delay line detector (DLD). Wires that detect electron beams are disposed in the DLD, enabling calculation of signal detection positions on the detector based on slight difference in arrival time of signals to both edges of the wires. Including a fluorescent plate between the MCP and the detector enables a photodetection type signal detector to be used as well.

A frame camera such as an ultra-high-speed camera or the like may be used as the ion detector 24. Ions with different arrival clock times to the signal detector are imaged in each imaging frame divided in extremely short time, so batch acquisition of ion distribution image data subjected to mass separation can be realized. Integrating multiple sets of such image data enables acquisition of mass spectral image data where multiple sets of mass spectral data have each been stored corresponding to the two-dimensional position thereof.

An arrangement also may be made where just ions 33 having a particular m/z are made to arrive at the ion detector 24, by installing a deflector or the like between the flight tube 23 and the ion detector 24. In this case, a CCD camera that does not have a timestamp function, or the like, can be used as the ion detector 24. The m/z of ions 33 passing through toward the ion detector 24 is selectively changed by consecutively changing the operation timing of the deflector.

In a pixel-type detector, the number of measurement points is a fixed value decided by the number of pixels. In a DLD, measurement position information is allocated to measurement points laid out in the form of a lattice beforehand. Note that the measurement points in a projection type are virtual measurement points represented by center positions of openings of a mesh that the observation region has been divided into. The measurement points correspond to pixel positions on the signal detector.

In a case of measuring a region wider than the observation region 32, the observation region 32 is sequentially moved over the surface of the sample 31, and the mass spectral image data, which is two-dimensional distribution data of the mass spectral data for each observation region 32 is acquired. The user drives the object moving device control unit 7 by operating the observation region instructing device 5 “hereinafter, simply “device 5”) to move the observation region 32 over the surface of the sample 31.

The ionization unit 1 ionizes the constituent on the surface of the sample 31 loaded on the sample table 3 within the observation region 32, and generates ions 33. Various types of ionization unit 1 may be used in the apparatus 100 in the embodiment. Examples of ionization methods of the ionization unit 1 include the photoionization method and the matrix-assisted laser desorption/ionization (MALDI) method, where the sample 31 is ionized by irraddation of a laser beam, the secondary ion mass spectrometry (SIMS) method where the sample 31 is irradiated a primary ion beam, and so forth. That is to say, the ionization unit 1 may be a light irradiating unit whereby the sample 31 is irradiated by light such as a laser beam, an ion irradiation unit whereby the sample 31 is irradiated by primary ions, or the like. Examples of primary ion beams in the SIMS method include ion beams of liquid metals such as Bi⁺, Ga⁺, and so forth, cluster ion beams of metals such as Bi³⁺, Au³⁺, and so forth, cluster ion beams of gasses of which the ingredients include argon, xenon, water, acid, alcohol, and so forth.

The ionization method that the ionization unit 1 performs may be an ionization method such as desorption electro-spray ionization (DESI) or scanning probe electro-spray ionization (SPESI). SPESI is a technique where a capillary that guides a liquid is used as a probe to generate an electro-spray while scanning the surface of a solid sample, thereby ionizing the sample, and the generated ions are subjected to mass spectrometry (Y. Otsuka et al., Rapid Commun. Mass Spectrom., 26, 2725-2732 (2012)).

The mass spectrometry unit 2 is the portion that performs mass spectrometry of the ions 33 generated by the ionization unit 1. The mass spectrometry unit 2 separates the ions 33 introduced by the mass spectrometry unit 2 according to their m/z, and detects each, thereby acquiring the m/z of the ions 33. Generally, multiple types of ions 33 are generated by the ionization unit 1 ionizing the sample 31, so the components included in the sample 31 before ionization can be estimated by performing mass spectrometry of the multiple types of ions 33.

Various types of mass spectrometry units 2 can be used in the apparatus 100 according to the embodiment. Examples of mass spectrometry units 2 include those performing quadrupole type, sector type, time-of-flight type, etc., mass spectrometry.

In a case of using a quadrupole or sector type mass spectrometer as the mass spectrometry unit 2, the path of flight of the ions 33 is changed by changing an electric field or magnetic field within the mass spectrometry unit 2. The electric field or magnetic field is scanned, and ions 33 reaching an ion detection unit (included in the mass spectrometry unit 2, omitted from illustration) installed at a predetermined position are detected. Accordingly, a mass spectrum, which is the ion detection intensity for each m/z, is acquired.

In a case of using a time-of-flight spectrometer as the mass spectrometry unit 2, the ions 33 are accelerated by application of an electric field or magnetic field. The accelerated ions 33 fly through the flight tube of the mass spectrometry unit 2 for a certain distance, and thereafter are detected by the ion detection unit (omitted from illustration).

The sample 31 is loaded on the sample table 3. The sample table 3 is further loaded on the object moving device 4, and fixed as to the object moving device 4. The object moving device 4 has an object moving function to move the sample 31 in directions parallel to the surface of the sample 31 loaded on the sample table 3, and is used to move the observation region 32. Although a screw feed or rack & pinion may be used for the object moving device 4, an arrangement having an actuator such as a stepping motor, ultrasonic motor, piezo device, or the like, is preferably used in precise movement control.

The control unit 6 is a unit that controls the object moving device control unit 7 so as to cooperate with the ionization unit 1, mass spectrometry unit 2, or analyzing unit 8. The control unit 6 outputs information specifying a position of the observation region 32 to the object moving device control unit 7. The object moving device control unit 7 controls the object moving device 4 to move the sample 31, thereby moving the observation region 32 to an intended position. The control unit 6 operates the ionization unit 1 at the observation region 32 thus positioned. The ions 33 emitted from the sample 31 are guided into the mass spectrometry unit 2, and subjected to detection and mass spectrometry. The mass spectral signals output from the mass spectrometry unit 2 are input to an input port of the control unit 6. The control unit 6 generates mass spectral image data in which are integrated position information on the surface of the sample 31 at points where ions 33 have been generated, and mass spectral data made up of m/z information and ion detection intensity. The mass spectral image data is output to the analyzing unit 8.

The analyzing unit 8 is a part that analyzes the mass spectral image data. The mass spectral image data is multi-dimensional data where mass spectral data is stored at points on an X-Y plane or an X-Y-Z space, and accordingly is not easily displayed on the display unit 9 as it is. The analyzing unit 8 analyzes the mass spectral image data to this end, and converts into two-dimensional or three-dimensional image data which can be displayed on the display unit 9.

Any analysis method can be used at the analyzing unit 8. For example, the ion intensity of just a particular m/z may be extracted from each mass spectral data and the distribution thereof may be output as two-dimensional image data. Alternatively, molecules included in the sample 31 may be identified by matching each mass spectral data with known mass spectral data in a database, and the distribution thereof output as two-dimensional image data. Alternatively, the mass spectral image data, which is multi-dimensional data, may be subjected to multivariate analysis, thereby estimating molecules in the sample 31 and the constitution and composition within the sample 31, which are output as two-dimensional image data. Note that an example has been described here regarding a case of mass spectral image data where mass spectral data is stored at points on an X-Y plane, but analysis can be performed in the same way regarding mass spectral image data being stored at points on an X-Y-Z space in the same way. In this case, three-dimensional image data can be acquired as the analysis results.

Now, multivariate analysis is a statistical technique where data relating to multiple variables is used to analyze the mutual relationship among these variables. Using multivariate analysis enables mass spectral data to be statistically classified based on the differences in spectral form of each mass spectral data. A judgment reference (classifier) is acquired regarding to which component or constituent each mass spectral data is to be assigned, and the judgment reference is applied to each mass spectral data. Thus, each mass spectral data is assigned to a component or constituent in the sample 31, so the distribution of each component can be converted into image data. The specific technique for performing the multivariate analysis can be selected from a variety of analysis methods, including principal component analysis, independent component analysis, multiple regression analysis, factor analysis, clustering, discrimination analysis, and so forth.

Note that the control unit 6 and analyzing unit 8 may be integrally configured within a personal computer (PC). Alternatively, part or all of processing performed by the control unit 6 and analyzing unit 8 may be executed by a field programmable gate array (FPGA) or application specific integrated circuit (ASIC) or the like, to improve speed of measurement or analysis.

The device 5 may be a mouse, keyboard, touch panel, or other like input device connected to the control unit 6 being shared, or may be a dedicated device having a joystick, trackball, or the like. Movement of the observation region 32 is performed by the control unit 6 or object moving device control unit 7 based on signals which the user has input using the device 5. The observation region 32 is sequentially moved from the current position thereof in accordance with the direction of movement and speed of movement of the observation region 32, input from the device 5. In a case where the device 5 is a joystick for example, the direction of movement and speed of movement can be input by the direction of tilt and angle of tilt of the joystick. Alternatively, in a case where the device 5 is a mouse, instructions can be given according to the direction of dragging and the movement speed of the mouse.

Alternatively, the user may input the route of movement of the observation region 32 beforehand using the device 5, so that the observation region 32 moves following this route. In this case, the route of movement of the observation region 32 is not restricted to a straight line, and may be curved. The route of movement of the observation region 32 may be displayed on the display unit 9 for user confirmation.

In a case where the ionization method is one where the ionization unit 1 performs irradiation of an ionization beam, such as a laser beam or primary ion beam, the movement of the observation region 32 can be realized by movement by the object moving device 4, deflection of the ionization beam, or a combination of both. The largest area which can be observed on the sample 31 is defined by the range of deflection of the ionization beam and the range of movement of the object moving device 4.

How the ionization beam is deflected is selected as appropriate depending on the type of ionization beam. In a case of using a laser beam as the ionization beam, deflection is performed by a reflection mirror, and in a case of using a primary ion beam as the ionization beam, deflection is performed using an electromagnetic field. Alternatively, the ionization beam may be deflected by mechanically changing the orientation of the ionization beam as to the sample 31.

The apparatus 100 according to the embodiment has a moving measurement mode where measurement is sequentially performed while moving the observation region 32, and a stationary measurement mode where measurement is performed while the observation region 32 is fixed (stationary). Changing of the measurement mode is performed by the control unit 6, based on an instruction by the device 5. At this time, the control unit 6 controls the object moving device 4 and ionization unit 1 conjunctively, or the object moving device 4 and mass spectrometry unit 2 conjunctively. That is to say, the control unit 6 according to the present embodiment switches measurement conditions depending on whether the observation region 32 is moving or fixed (stationary). In other words, the control unit 6 in the embodiment is a switching unit that switches measurement conditions depending on whether in the moving measurement mode or stationary measurement mode. More specifically, the control unit 6 switches the measurement conditions of mass spectrometry of ions 33 in conjunction with moment of the observation region 32 by the object moving device 4, and switches analysis conditions of the mass spectral image data performed at the analyzing unit 8.

Note that “measurement” as used in the embodiment implies ionizing the sample 31 within the observation region 32 by the ionization unit 1, performing mass spectrometry of the generated ions 33 by the mass spectrometry unit 2, and acquiring mass spectral data regarding multiple measurement points within the observation region 32. That is to say, the “measuring unit” that performs measurement in the embodiment includes the ionization unit 1 and the mass spectrometry unit 2. Although measurement conditions will be described in detail later, this refers to the number of measurement points, the number and value range of m/z's for detection, the accumulation number at the same measurement point (or same observation region), and so forth.

When observing with the movement of the observation region 32 stopped (stationary measurement mode), display of a precise analysis image is required, so measurement and analysis taking time is often permissible. However, on the other hand, when observing while moving the observation region 32 (moving measurement mode), such as in a case of searching for a desired observation region, the analysis image has to be displayed quickly even if the analysis image is rougher than when observing with the observation region 32 stopped. Accordingly, the apparatus 100 according to the embodiment effects control so that the measurement conditions and analysis conditions when moving are coarser than the measurement conditions and analysis conditions when fixed (stationary). Here, “coarse conditions” implies measurement conditions where the number of data acquisition points is smaller, i.e., less time required for measurement, and analysis conditions requiring less time for analysis.

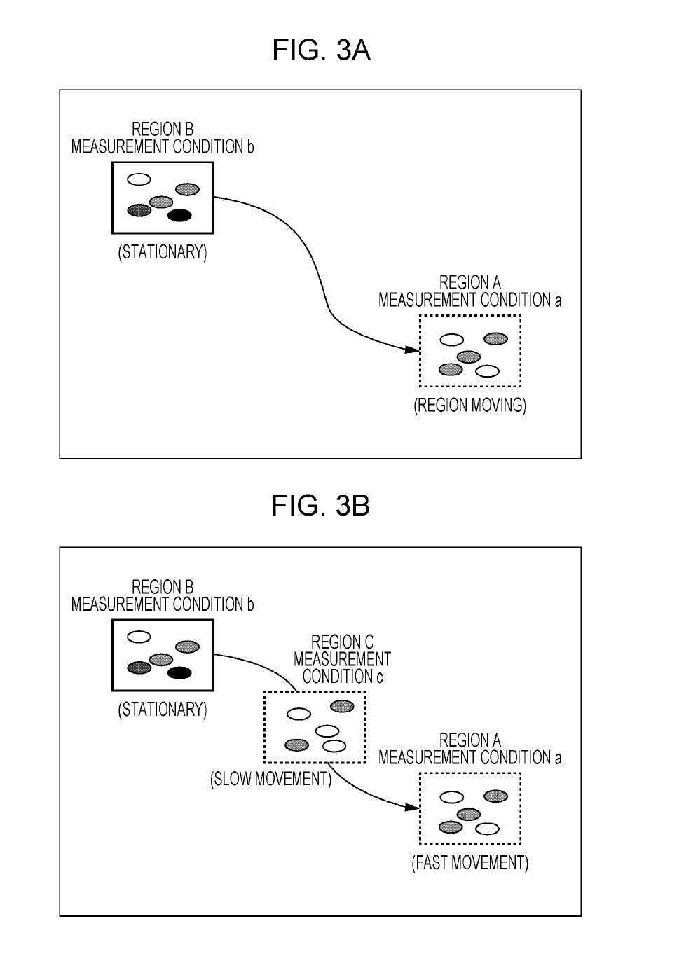

FIGS. 3A and 3B are schematic diagrams illustrating a relationship regarding switching measurement conditions when the observation region 32 is moving and when stationary. That is to say, when the observation region 32 is moving, measurement is performed under measurement conditions a in a region A, and is switched to measurement conditions b in a region B when the observation region 32 is stationary (FIG. 3A). The apparatus 100 may also be configured so that the movement state (movement speed) of the observation region 32 is determined and the measurement conditions are automatically switched.

Alternatively, the apparatus 100 according to the embodiment may be configured so as to automatically switch measurement conditions in multi-step or steplessly in accordance with the movement speed of the observation region 32. FIG. 3B illustrates an example of switching in three stages. Measurement is performed under measurement conditions a in the region A when the movement speed of the observation region 32 is fast (during fast movement), and measurement is performed under measurement conditions c in the region C when the movement speed of the observation region 32 is slow (during slow movement). Measurement is performed under measurement conditions b in region B when stationary (region fixed). Now, measurement conditions a are coarser measurement conditions than measurement conditions c, and measurement conditions c are coarser measurement conditions than measurement conditions b. In this way, changing measurement conditions according to the movement speed of the observation region 32 enables performing as detailed a measurement and image display as possible, while tracking the movement of the observation region 32.

The measurement conditions in the moving measurement mode and stationary measurement mode may be set beforehand. Alternatively, the control unit 6 may perform back calculation of measurement time suitable for the movement speed of the observation region 32, and automatically decide calculation conditions in the moving measurement mode based on the results. Alternatively, the control unit 6 may decide the measurement conditions in the stationary measurement mode based on the measurement results or analysis results in the moving measurement mode.

One conceivable case of using the moving measurement mode is a case where the observation region 32 is moved to perform observation over a wide range of the sample, so as to look for an observation region 32 for performing detailed observation, for example. The results of analysis can be quickly displayed by using measurement conditions or analysis conditions that take little time for measurement or analysis. Accordingly, even if many movement steps are set at close intervals to move the observation region 32, the observation region 32 can be smoothly moved. The measurement conditions or analysis conditions at this time are preferably set within a range where the presence of different kinds of substances can be distinguished even if spatial resolution or substance identifying capabilities are low.

A conceivable case of using the stationary measurement mode is a case where an observation region 32 to be observed in detail is decided, the observation region 32 is moved, and then the movement is stopped to observe in detail. The measurement or analysis conditions are set to conditions where higher spatial resolution or more detailed spectral information is obtained as compared to the conditions for the moving measurement mode.

Examples of measurement conditions or analysis conditions which the control unit 6 switches will be described as embodiments according to the present invention. Note that measurement conditions or analysis conditions which the control unit 6 switches may be multiple combined conditions of the conditions exemplarily illustrated below in the embodiments.

### First Embodiment

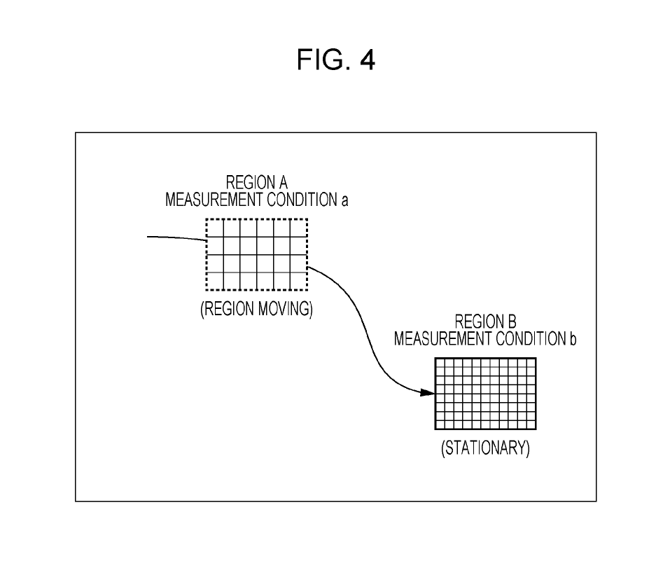

As a first embodiment, a case will be described where the measurement conditions for the control unit 6 to switch are the number of measurement points, with reference to FIGS. 1 and 4. Note that the intersections in the lattice in each region in FIG. 4 schematically represent measurement points.

First, description will be made regarding a case where the apparatus 100 is a scanning type mass microscope apparatus. In a scanning type mass microscope apparatus, the range of the observation region 32 and the number of measurement points are set, the distance between the measurement points is decided by the control unit 6 based on the parameters, and the positions of the measurement points within the observation region 32 are decided. Thereafter, ionization of the sample 31 at local regions nearby the measurement points is performed by the ionization unit 1 while scanning over the measurement points on the sample 31, and mass spectrometry of the generated ions 33, are repeated. Reducing the number of measurement points lowers the spatial resolution, but is advantageous in that measurement time and analysis time can be reduced since the number of data acquisition points is smaller. Accordingly, the number of measurement points to be measured by the measuring unit is controlled by switching by the control unit 6 serving as the switching unit as follows, between the moving measurement mode and the stationary measurement mode according to the present embodiment.

[1] Moving measurement mode: The number of measurement points is set to a smaller number of measurement points as compared with the stationary measurement mode (region A in FIG. 4). When measurement of the measurement points in the observation region 32 ends, the observation region 32 is moved to the next position by the object moving device 4 and so forth.

[2] Stationary measurement mode: The number of measurement points is set to a value larger than the number of measurement points in the moving measurement mode (region B in FIG. 4).

In a TOF-SIMS type mass microscope apparatus, the number of measurement points is assumed to be 512 points on both the X direction and the Y direction (i.e., a total of 262,144 points). At this time, assuming the amount of time required to acquire a mass spectrum for one measurement point (i.e., the maximum flying time calculated at the mass spectrometry unit 2) to be 100 μs, approximately 26 seconds is necessary to measure all measurement points. On the other hand, in a case where the measurement points are made coarser (the number of measurement points made smaller), so that there are 64 points on both the X direction and the Y direction (i.e., a total of 4,096 points), the amount of time required to measure all measurement points can be reduced to 0.4 seconds.

Also, reducing the number of measurement points can reduce the number of points of mass spectral data acquired for each observation region. That is to say, the data size of the mass spectral image data can be reduced. Consequently, the amount of time required for the analyzing unit 8 to analyze the mass spectral image data can also be shortened. As a result, observation results can be quickly displayed while tracking the motion of the observation region.

In a case where the signal intensity of ion signals is weak, a valid technique is to perform measurement of the same measurement point multiple times, and to accumulate the signals obtained by the multiple measurements. This can improve the S/N ratio and also improve the identification accuracy of the substance and spatial resolution. On the other hand, there are cases where sufficiently strong signals are obtained even with a small accumulation number, such as when detecting elements or molecules which are plenty in the sample. These signals can be effectively used in a case of performing a high-speed preview measurement (measurement performed moving over the observation region while displaying measurement results partway through moving through the observation region).

Accordingly, an arrangement may be made where the accumulation number also changes depending on whether in the moving measurement mode or in the stationary measurement mode. In the moving measurement mode, capabilities to track the motion of the observation region is demanded, so the amount of time required from measurement to displaying of the image is reduced by setting the accumulation number so as to be small. On the other hand, in the stationary measurement mode, more precise measurement is demanded than when the observation region is moving, so the accumulation number is preferably increased.

The present embodiment can also be applied in a case where the apparatus 100 is a projection type mass microscope apparatus. In a projection type mass microscope apparatus, the ionization beam is defocussed and the sample 31 is irradiated, thereby performing batch ionization of the sample 31 within the observation region 32. Thereafter, the discharged ions 33 each reach the ion detector while maintaining their positional information. Accordingly, the positions on the sample 31 within the observation region 32 from which the ions 33 have been discharged correspond with the detection positions on the ion detector, in a one-on-one manner. That is to say, in a projection type mass microscope apparatus, the number of measurement points is defined by the number of detection points on the ion detector that is decided by the detectable region of the ion detector and the spatial resolution of detection.

In a case of applying the present embodiment to a projection type mass microscope apparatus, the control unit 6 switches the number of detection points detected by the ion detector. The control unit 6 can reduce the image data size of the acquired mass spectral image data, by thinning out the number of detection points at which the ion detector performs detection. Alternatively, the data size of the mass spectral image data may be reduced by, instead of changing the number of detection points which the ion detector detects, the acquired mass spectral image data being compressed by the control unit 6 or the analyzing unit 8. In this case, the mass spectral data included in the mass spectral image data can be thinned out by any method, thereby realizing compression. Alternatively, compression may be performed by averaging the mass spectral data of pixels of the mass spectral image with that of surrounding pixels.

According to the present embodiment as described above, if the observation region is moved, the control unit 6 effects control so that the number of measurement points can be switched as measurement conditions at the measuring unit. Accordingly, measurement results can be quickly displayed as an image, tracking the movement of the observation region, thus facilitating searching for a desired observation region where detailed observation is to be performed.

### Second Embodiment

As a second embodiment, a case will be described where the measurement conditions for the control unit 6 to switch are the number of m/z regarding which the mass spectrometry unit 2 performs detection, with reference to FIGS. 1, 2, and 5A and 5B.

In a case where a mass spectrometry unit of a type which performs measurement by scanning the m/z over a certain range, such as a quadrupole type, sector type, or the like, for example, is used as the mass spectrometry unit 2, the measurement time at each measurement point is defined as the scan time for the m/z. Accordingly, instead of detecting and measuring all m/z within the measureable range, selecting part of the m/z and performing detection and measurement regarding these m/z only, enables the measurement time to be reduced. This also reduces the data size of the mass spectral data, and accordingly further reduces the data size of the mass spectral image data. Consequently, the amount of time required for the analyzing unit 8 to analyze the mass spectral image data can also be reduced.

On the other hand, in a case where a time-of-flight mass spectrometry unit is used as the mass spectrometry unit 2, the measurement time is defined as the largest value of the time-of-flight measured (i.e., the largest value of the detected m/z). Accordingly, there are cases where the measurement time may not be reduced even if detection and measurement is performed only regarding a selected part of the m/z's. However, the data size of the mass spectral image data is smaller even in such cases, so the amount of time required for the analyzing unit 8 to analyze the mass spectral image data can be reduced.

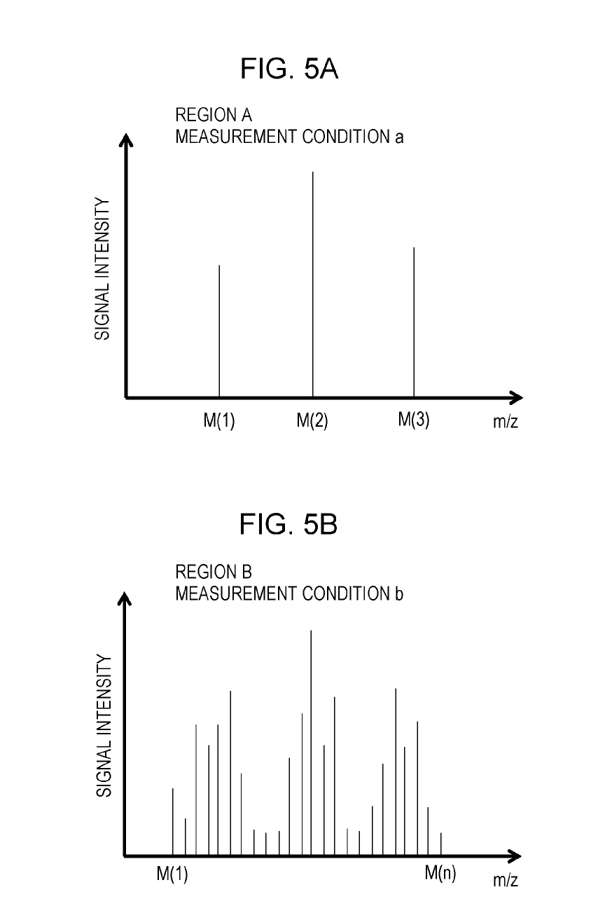

Accordingly, in the present embodiment, the number of m/z's that the mass spectrometry unit 2 detects is controlled by switching by the control unit 6 serving as the switching unit as follows, between the moving measurement mode and the stationary measurement mode. FIGS. 5A and 5B are schematic diagrams illustrating mass spectral data at a certain measurement point. Note that M(n) represents, of the set number of m/z's, the n′th m/z from the smallest m/z.

[1] Moving measurement mode: The number of m/z's that the mass spectrometry unit 2 detects is set to a smaller number of m/z's as compared with the stationary measurement mode (FIG. 5A). When measurement of the measurement points in the observation region 32 ends, the observation region 32 is moved to the next position by the object moving device 4 and so forth.

[2] Stationary measurement mode: The number of m/z's that the mass spectrometry unit 2 detects is set to a value larger than the number of measurement points in the moving measurement mode (FIG. 5B).

Reducing the number of m/z's for the mass spectrometry unit 2 to detect enables the amount of time from measurement to display of analysis results to be reduced. Reducing the number of m/z's that the mass spectrometry unit 2 detects does reduce the substance identifying capabilities, but distinguishing the shape of the region where the substance is present and different kinds of substances can be performed if the m/z ratio is set appropriately. On the other hand, increasing the number of the m/z's that the mass spectrometry unit 2 detects increases the amount of time required for measurement and analysis, but a more detailed spectrum can be obtained, enabling more detailed observation.

Note that the way of selecting m/z's to be detected by the mass spectrometry unit 2 is not restricted in particular. That is to say, the m/z's may be selected equidistantly from the range of detectable m/z's, or non-equidistantly. When selecting m/z's to be detected by the mass spectrometry unit 2, selection may be performed based on spectral information of known substances. For example, m/z's with strong detection intensity in a spectrum of a known substance are selected and set.

Note that the present embodiment may also be applied to a projection type mass microscope apparatus 200. An example of selecting just the selected m/z's, in a case of using a time-of-flight mass spectrometry unit as the mass spectrometry unit 2, will be described. In a case of using a pixel type ion detector as the ion detector 24 in FIG. 2, the ion detector 24 performs detection of ions 33 for all m/z's. Thereafter, the control unit 6 or the analyzing unit 8 selects only data regarding the necessary m/z's, out of all data output from the ion detector 24. In a case of using a frame type ion detector as the ion detector 24 in FIG. 2, there are two types of methods depending on the shutter setting method of the ion detector 24. In types where the shutter timing of the ion detector 24 can be freely set, the shutter is set so as to operate a timings corresponding to the m/z's selected beforehand. In types where the operation timing of the shutter of the ion detector 24 is set consecutively for equal intervals, the control unit 6 selects data of frames corresponding to the necessary m/z's, and transfers this to the analyzing unit 8.

In the present embodiment as well, the accumulation number may be changed depending on whether the moving measurement mode or the stationary measurement mode. In this case, the number of m/z's that the mass spectrometry unit 2 detects may be fixed, or may be changed.

According to the present embodiment as described above, when the observation region is moved, the control unit 6 effects control so that the number of m/z's detected by the mass spectrometry unit 2 as measurement conditions can be switched. Accordingly, measurement results can be quickly displayed as an image, tracking the movement of the observation region, thus facilitating searching for a desired observation region where detailed observation is to be performed.

### Third Embodiment

A modification of the second embodiment will be described as a third embodiment. In a case where the sample 31 is a biological sample, lighter elements such as hydrogen, sodium, and so forth are often plentifully included in the sample 31. Accordingly, there are cases where general morphologic information of the surface of the sample 31 can be obtained by mapping the distribution of these light elements.

These elements are abundant in the sample 31, which is advantageous in that measuring these elements yields sufficient signal intensity with a small accumulation number. Also, the number of m/z's to be detected can be reduced by reducing the value range of the m/z's to be detected and detecting only ions with a small m/z. Accordingly, the number of data acquisition points can be reduced, and the amount of time necessary for measurement and the amount of time necessary for analysis can be reduced. Further, in a case of using a time-of-flight mass spectrometry unit as the mass spectrometry unit 2, reducing the maximum value of the m/z's to be detected can reduce the time of flight for detection, thereby reducing the amount of time necessary for measurement.

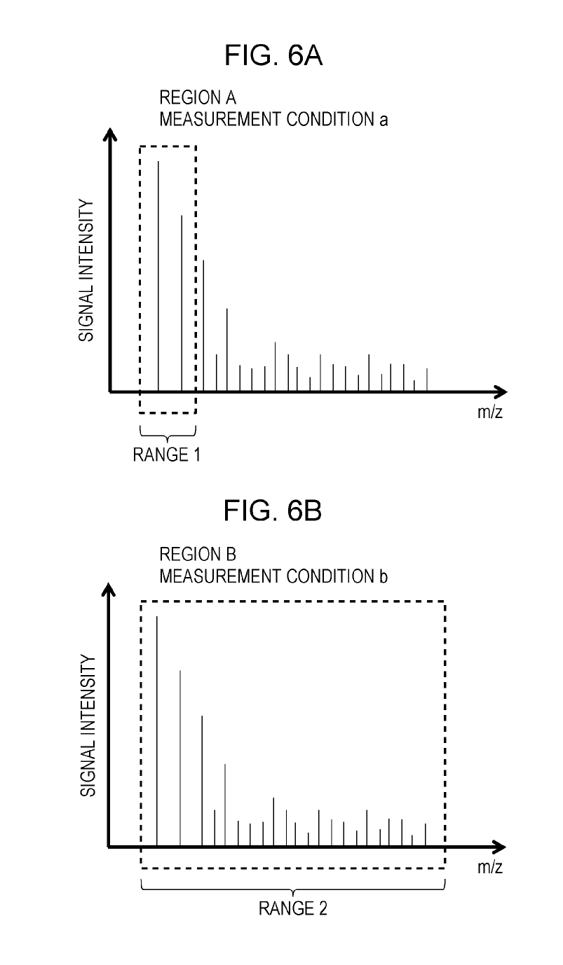

Accordingly, in the present embodiment, the control unit 6 performs switching as follows, between the moving measurement mode and the stationary measurement mode.

[1] Moving measurement mode: The value range of m/z's to be detected is set to a narrower range as compared to the stationary measurement mode (FIG. 6A). The value range of m/z's at this time may be set as measurement conditions A represented by range 1, so as to include m/z's with strong signal intensity. Alternatively, just one or more particular m/z's having strong signal intensity may be selected and set as the m/z's to be detected. When measurement of the measurement points in the observation region 32 ends, the observation region 32 is moved to the next position by the object moving device 4 and so forth.

[2] Stationary measurement mode: The value range of m/z's to be detected is set to measurement conditions B represented by range 2, which is a broader range as compared to the moving measurement mode (FIG. 6B). Acquiring m/z's over a broad range enables detailed mass spectral image data to be acquired.

In the present embodiment as well, the accumulation number may be changed depending on whether the moving measurement mode or the stationary measurement mode, in the same way as in the first embodiment.

According to the present embodiment as described above, when the observation region is moved, the control unit 6 effects control so that the value range of m/z's to be detected by the mass spectrometry unit 2 as measurement conditions can be switched. Accordingly, measurement results can be quickly displayed as an image, tracking the movement of the observation region, thus facilitating searching for a desired observation region where detailed observation is to be performed.

### Fourth Embodiment

As a fourth embodiment, a case where the control unit 6 switches the analysis method (analysis conditions) of the mass spectral data which the analyzing unit 8 performs, depending on whether the moving measurement mode or the stationary measurement mode. When analyzing mass spectral data, if the m/z of parent ions or fragment ions is known regarding the substance, the type of molecule can be identified by matching with a database. Even if the m/z of the substance is unknown, it is possible to distinguish the substance by classifying the spectrums in the mass spectral data by difference in the spectral form.

Performing multivariate analysis as the analysis of the mass spectral data enables the mass spectral data to be classified into substances or components including multiple substances, or the like, based on similarity in spectral form, and so forth. Even if the acquired mass spectral data is complex multispectral data originating from multiple signal sources (substances), the spectrums originating from each substance can be separated and extracted.

Now, “multivariate analysis” is a statistical technique where data relating to multiple variables is used to analyze the mutual relationship among these variables. In the case of the present embodiment, each mass spectral data can be classified by analyzing the mutual relationship of signal intensities in different m/z's, and finding to which substance each belongs. In the present embodiment, the term “base vector” means a judgment reference regarding to which component each spectrum belongs. By applying the base vector to each mass spectral data, a score as to the base vector can be yielded corresponding to each component. The type of multivariate analysis is not restricted in the present embodiment, and a variety of analysis methods can be applied, including principal component analysis, independent component analysis, multiple regression analysis, factor analysis, clustering, discrimination analysis, self-organizing map, and so forth.

As the dimensions of mass spectral data to be analyzed increase, i.e., as the number of m/z's in the mass spectral data increases, the data size of the mass spectral image data also increases. Depending on the type of multivariate analysis, the amount of calculations may markedly increase when the data size increases, and the amount of time necessary for analysis may markedly increase depending on the technique. For example, in principal component analysis, as many base vectors as there are signal dimensions need to be calculated, so the analysis time will markedly increase depending on the dimensions of the data to be analyzed.

Accordingly, in the present embodiment, the control unit 6 performs switching of the analysis method (analysis conditions) to be performed by the analyzing unit 8 as follows, between the moving measurement mode and the stationary measurement mode.

[1] Moving measurement mode: The constituents are roughly separated by simple analysis, such as comparing signal intensity at a particular m/z, or the like.

[2] Stationary measurement mode: The analysis method is switched to a method that can perform more detailed analysis than in the moving measurement mode. For example, detailed spectral analysis is performed by multivariate analysis. Additionally, measurement conditions, such as the number of m/z's to be detected, the value range thereof, the number of measurement points, and so forth may be made to be larger than in the moving measurement mode.

The analysis technique to be switched between the moving measurement mode and the stationary measurement mode can be optionally selected from various analysis techniques. The same analysis technique or different analysis techniques may be selected to be switched between the moving measurement mode and the stationary measurement mode. For example, the technique of multivariate analysis may be switched between the moving measurement mode and the stationary measurement mode. An example is a configuration where primary component analysis is performed as the analyzing method in the moving measurement mode, while independent component analysis is performed in the stationary measurement mode. Note that independent component analysis has a greater number of calculations per unit data amount as compared to primary component analysis, but has higher separation capabilities of constituents included in the sample. Further, multiple multivariate analysis techniques may be combined in each of the moving measurement mode and stationary measurement mode. Particularly, combining primary component analysis and independent component analysis in the stationary measurement mode can further improve separation capabilities and identification of constituents included in the sample.

Also, data acquired in the moving measurement mode, or the analysis results of that data, may be used in analysis in the stationary measurement mode. Accordingly, the amount of time required for analysis in the stationary measurement mode can be reduced, in particular when performing multivariate analysis as the analysis method. That is to say, the amount of time required for analysis can be reduced by applying a base vector, calculated in analysis of mass spectral image data previously acquired, to mass spectral image data acquired in a new observation region, and calculating a score. The base vector used at this time may be a base vector calculated from mass spectral image data acquired from a single observation region, or may be a base vector calculated from data obtained by integrating multiple sets of mass spectral image data acquired from multiple observation regions. Performing calculation of base vectors and acquisition of mass spectral image data in parallel at this time is efficient.

Alternatively, the mass spectral image data acquired at different m/z's that have been coarsely selected in the moving measurement mode may be sequentially integrated, and a base vector calculated from data reconstructed from the integrated data as mass spectral image data for a great number of m/z's. Analyzing mass spectral image data acquired in a new observation region using a base vector calculated in this way enables separation capabilities of components included in the sample to be improved, while suppressing increase in time required for analysis.

### Fifth Embodiment

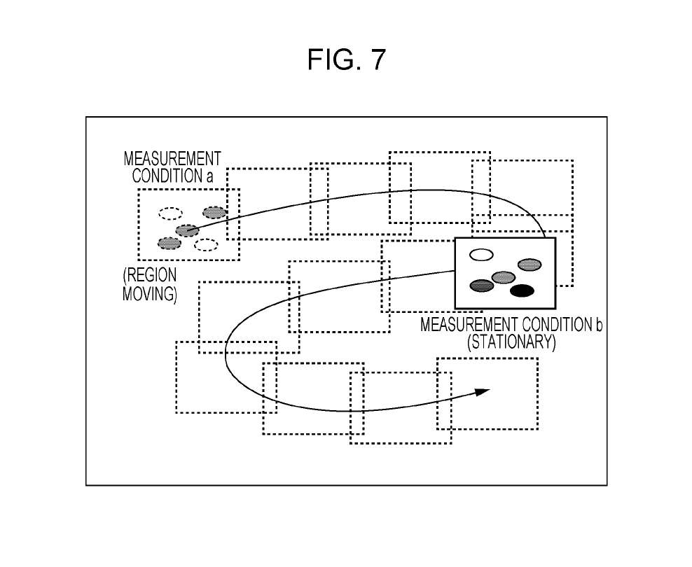

An embodiment where a wide-range preview display is performed while moving and observing a narrow region, will be described as a fifth embodiment, with reference to FIG. 7. When observing biological samples for pathological diagnosis, wide regions in the order of millimeters need to be observed. While it is ideal to observe a wide region in the order of millimeters in detail, observing the entire region in detail would take a tremendous amount of time. Accordingly, in order to reduce the amount of time required for analysis, there is a method for the observer to first coarsely observe the wide region in the order of millimeters (preview), and then select a region from this regarding which there is need to observe in further detail.

Even during preview observation, the form and composition of the sample 31 within the observation region 32 is preferably observed in detail to a certain extent. Accordingly, the size of each observation region 32 is restricted to around 100 μm to 500 μm square. This means that in order to preview a wide range over several millimeters square, the images acquired from a great number of observation regions (narrow regions) need to be tiled to configure a preview display.

Accordingly, in the present embodiment, the mass microscope apparatus 100 is operated as follows, to realize a preview display that is not stressful for the observer.

[1] When performing preview measurement: The observation region 32 is sequentially moved to adjacent or dispersed positions and measurement is performed in the moving measurement mode. A great number of analysis results (images) thus acquired are laid out so as to correspond to the respective positions on the sample 31 in each observation region 32, thereby forming a wide-region combined image. Note that the observation region 32 is moved by the object moving device 4 and so forth.

The control unit 6 preferably switches the measurement conditions or analysis conditions in the moving measurement mode, as in the above-described embodiments. While conditions to change are preferably selected as appropriate depending to the type of the measuring unit (scanning type/projection type, mass spectrometry method, two-dimensional detection unit, etc.).

How the observation region 32 moves may be set beforehand, or the control unit 6 may sequentially set narrow regions so as to follow a path which the observer has drawn by operating the device 5. The display of observation results may either be images of the narrow region displayed in order of observation, or be a combined image displayed at once after observation of the wide region is completed.

Analysis may be performed each time a narrow region is measured and an image displayed thereof, or multiple narrow regions may be measured, data of a wide region thereof analyzed, and the results displayed as an image. Multivariate analysis and the like may be performed at this time to generally color code the distribution of components, or the like, in the display.

[2] When performing main measurement (detailed measurement): The observer selects a narrow region based on the preview image, and performs detailed observation (main measurement) under measurement conditions or analysis conditions that are more detailed as compared to when performing preview measurement, in that narrow region. At this time, the observer can select one narrow region from the multiple narrow regions making up the wide-area preview image, as an observation region for main measurement. Alternatively, an observation region for main measurement may be set by the observer instructing any region on the preview image. At the time of main measurement, the control unit 6 effects control to switch to measurement conditions with a greater number of data acquisition points, or more detailed analysis conditions.

According to the present embodiment, a mass microscope apparatus can be realized which speedily gives a preview display of a wide area when searching for a desired observation region.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-206015, filed Oct. 6, 2014, which is hereby incorporated by reference herein in its entirety.

What is claimed is:

1. A mass microscope apparatus comprising:
a measuring unit including
an ionization unit configured to ionize a sample present in an observation region, and
a mass spectrometry unit configured to perform mass spectrometry of ions generated by the ionization unit;
an object moving device configured to relatively move the observation region as to the sample; and
a switching unit configured to switch measurement conditions of the measuring unit depending on whether the mass microscope apparatus is operating in
a moving measurement mode where the observation region is moved by the object moving device to sequentially perform measurement by the measuring unit, and
a stationary measurement mode where the observation region is stationary and measurement is performed by the measuring unit.

2. The mass microscope apparatus according to claim 1,
wherein the measuring unit is configured to acquire a two-dimensional distribution of the ions in the observation region.

3. The mass microscope apparatus according to claim 1,
wherein the switching unit sets measurement conditions in the stationary measurement mode, in accordance with measurement results in the moving measurement mode.

4. The mass microscope apparatus according to claim 2,
wherein the switching unit sets measurement conditions in the stationary measurement mode, in accordance with measurement results in the moving measurement mode.

5. The mass microscope apparatus according to claim 1,
wherein the switching unit sets measurement conditions so that a total number of data acquisition points in the moving measurement mode is smaller than a total number of data acquisition points in the stationary measurement mode.

6. The mass microscope apparatus according to claim 1,
wherein the measurement conditions are a total number of observation points within the observation region.

7. The mass microscope apparatus according to claim 1,
wherein the measurement conditions are at least one of a total number of mass-to-charge ratios to be detected in the measurement and a value range of mass-to-charge ratios to be detected in the measurement.

8. The mass microscope apparatus according to claim 1,
wherein the measurement conditions are an accumulation number of mass spectral data in the same observation region.

9. The mass microscope apparatus according to claim 1,
wherein the switching unit switches the measurement conditions of the measuring unit in accordance with the speed of movement of the observation region by the object moving device.

10. The mass microscope apparatus according to claim 1, further comprising:
an analyzing unit configured to analyze mass spectral data acquired by the mass spectrometry unit.

11. The mass microscope apparatus according to claim 10, wherein the switching unit further switches the analysis conditions of the analyzing unit depending on whether the mass microscope apparatus is in the moving measurement mode or in the stationary measurement mode.

12. A mass microscope apparatus comprising:
a measuring unit including
an ionization unit configured to ionize a sample present in an observation region, and
a mass spectrometry unit configured to perform mass spectrometry of ions generated by the ionization unit;
an object moving device configured to relatively move the observation region as to the sample;
an analyzing unit configured to analyze mass spectral data acquired by the mass spectrometry unit; and
a switching unit configured to switch analysis conditions of the analyzing unit depending on whether the mass microscope apparatus is operating in
a moving measurement mode where the observation region is moved by the object moving device to perform measurement by the measuring unit, and
a stationary measurement mode where the observation region is stationary and measurement is performed by the measuring unit.

13. The mass microscope apparatus according to claim 12,
wherein the switching unit performs switching so that the analyzing unit performs multivariate analysis on the mass spectral data in at least the stationary measurement mode.

14. The mass microscope apparatus according to claim 12,
wherein the analysis conditions are selected from the same type of multivariate analysis technique, and the analysis results in the moving measurement mode are used in analysis in the stationary measurement mode.

15. The mass microscope apparatus according to claim 1,
wherein, in the moving measurement mode, measurement is performed while sequentially moving a narrow region, the observation results of the regions are displayed in preview as an wide area image so that the positional relationship of the observation regions on the sample are maintained, and a region for observation in the stationary measurement mode is selected from the regions in the preview display.

16. The mass microscope apparatus according to claim 1,
wherein the mass spectrometry unit is a projection type mass spectrometry unit.

17. The mass microscope apparatus according to claim 1,
wherein the ionization unit is an ion irradiation unit configured to irradiate the sample by primary ions.

18. The mass microscope apparatus according to claim 12,
wherein the ionization unit is an ion irradiation unit configured to irradiate the sample by primary ions.

19. The mass microscope apparatus according to claim 1,
wherein the ionization unit is a light irradiation unit configured to irradiate the sample by light.

20. The mass microscope apparatus according to claim 12,
wherein the analysis conditions are selected from different types of multivariate analysis techniques, and the analysis results in the moving measurement mode are used in analysis in the stationary measurement mode.
